(19) United States
(12) Patent Application Publication
(10) Pub. No.: US 2025/0265384 A1
(43) Pub. Date: Aug. 21, 2025

(54) DIGITAL TWIN FEDERATION APPARATUS AND METHOD

(71) Applicant: ELECTRONICS AND TELECOMMUNICATIONS RESEARCH INSTITUTE, Daejeon (KR)

(72) Inventors: Myung-Sun BAEK, Daejeon (KR); Won-Jae SHIN, Daejeon (KR); Young-Soo PARK, Daejeon (KR); Eui-Suk JUNG, Daejeon (KR)

(21) Appl. No.: 18/988,725

(22) Filed: Dec. 19, 2024

(30) Foreign Application Priority Data
Feb. 19, 2024 (KR) 10-2024-0023726
Aug. 27, 2024 (KR) 10-2024-0115032

(51) Int. Cl. G06F 30/20; G06F 16/178

(52) U.S. Cl. CPC G06F 30/20; G06F 16/178

(57) ABSTRACT

Disclosed herein are a digital twin federation apparatus and method. The digital twin federation apparatus includes memory configured to store at least one program, and a processor configured to execute the program, wherein the program performs extracting at least two digital twin systems corresponding to digital twin types matching a service purpose, received from an application service layer, from a pre-registered digital twin system list, obtaining pieces of data from the extracted at least two digital twin systems, respectively, synchronizing the pieces of data obtained from the extracted at least two digital twin systems, respectively, so that the pieces of data are linked in an identical time slot and in an identical unit, and delivering the linked data to the application service layer.

### CROSS REFERENCE TO RELATED APPLICATIONS

This application claims the benefit of Korean Patent Application Nos. 10-2024-0023726, filed Feb. 19, 2024 and 10-2024-0115032, filed Aug. 27, 2024, which are hereby incorporated by reference in their entireties into this application.

### BACKGROUND OF THE INVENTION

### 1. Technical Field

The following embodiments relate to digital twin technology.

### 2. Description of the Related Art

A digital twin is technology that digitally replicates various objects (people, things, and spaces) in the real world and solves or optimizes the problems of the real world by conducting various simulations in the digital world at low cost based on the replicated objects.

Until now, digital twin technology has been designed and developed to target a single system or a single process.

The concept of the digital twin has continued to evolve and is primarily developed and utilized to optimize industrial processes or equipment in manufacturing fields. Additionally, the number of cases where digital twins are applied to public services, such as river management and port management, at the government level is gradually increasing.

However, there is a need to construct a large-scale digital twin so as to construct digital twins at the city or national level, or to solve complex problems and optimize systems. In large-scale digital twin construction, the number of objects included in the digital twin, the number of target models, etc. increase significantly, thus leading to an exponential rise in the complexity of implementation and management.

### SUMMARY OF THE INVENTION

An embodiment is intended to facilitate the construction of a digital twin targeting a large-scale physical world at the city or national level.

An embodiment is intended to reduce cost, time and complexity attributable to the construction of a large-scale digital twin.

In accordance with an aspect, there is provided a digital twin federation apparatus, including memory configured to store at least one program, and a processor configured to execute the program, wherein the program performs extracting at least two digital twin systems corresponding to digital twin types matching a service purpose, received from an application service layer, from a pre-registered digital twin system list; obtaining pieces of data from the extracted at least two digital twin systems, respectively; synchronizing the pieces of data obtained from the extracted at least two digital twin systems, respectively, so that the pieces of data are linked in an identical time slot and in an identical unit, and delivering the linked data to the application service layer.

The program may further perform registering at least one digital twin system, and providing a data input/output interface of the registered at least one digital twin system.

The program may perform, in registering, identifying a type of a digital twin system requested to be newly registered, delivering a metadata system corresponding to the identified type of the digital twin system to the corresponding digital twin system, and receiving metadata generated by the digital twin system based on the metadata system.

The program may perform, in identifying, determining whether the identified type of the digital twin system is included in types of previously held digital twin systems.

The program may perform, in delivering, when the identified type of the digital twin system is a type of a previously held digital twin system, delivering a previously held metadata system to the digital twin system.

The program may perform, in delivering, when the identified type of the digital twin system is not a type of a previously held digital twin system, delivering a metadata standard system of a digital twin system having a type similar to that of the corresponding digital twin system to the digital twin system.

The program may further include determining whether an error occurs in the obtained data and validating an operation of the corresponding digital twin system.

The program may perform, in validating, simply determining only whether an error and an anomaly are present in data requiring near real-time processing.

The program may perform, in validating, when data has high importance, validating pieces of data of the two or more digital twin systems using individual units or validating the pieces of data by linking the data based on a correlation.

The program may perform, in synchronizing, checking metadata, unifying units of pieces of data when the units of the pieces of data are different from each other, and linking the pieces of data by synchronizing times or output timestamps between the pieces of data so that the pieces of data are federated and used.

In accordance with another aspect, there is provided a digital twin federation method, including extracting at least two digital twin systems corresponding to digital twin types matching a service purpose, received from an application service layer, from a pre-registered digital twin system list, obtaining pieces of data from the extracted at least two digital twin systems, respectively, synchronizing the pieces of data obtained from the extracted at least two digital twin systems, respectively, so that the pieces of data are linked in an identical time slot and in an identical unit, and delivering the linked data to the application service layer.

The digital twin federation method may further include registering at least one digital twin system, and providing a data input/output interface of the registered at least one digital twin system.

The registering may include identifying a type of a digital twin system requested to be newly registered, delivering a metadata system corresponding to the identified type of the digital twin system to the corresponding digital twin system, and receiving metadata generated by the digital twin system based on the metadata system.

The identifying may include determining whether the identified type of the digital twin system is included in types of previously held digital twin systems.

The delivering may include, when the identified type of the digital twin system is a type of a previously held digital twin system, delivering a previously held metadata system to the digital twin system.

The delivering may include, when the identified type of the digital twin system is not a type of a previously held digital twin system, delivering a metadata standard system of a digital twin system having a type similar to that of the corresponding digital twin system to the digital twin system.

The digital twin federation method may further include determining whether an error occurs in the obtained data and validating an operation of the corresponding digital twin system.

The validating may include simply determining only whether an error and an anomaly are present in data requiring near real-time processing.

The validating may further include, when data has high importance, validating pieces of data of the two or more digital twin systems using individual units or validating the pieces of data by linking the data based on a correlation.

The synchronizing may include checking metadata, unifying units of pieces of data when the units of the pieces of data are different from each other, and linking the pieces of data by synchronizing times or output timestamps between the pieces of data so that the pieces of data are federated and used.

### BRIEF DESCRIPTION OF THE DRAWINGS

The above and other objects, features and advantages of the present disclosure will be more clearly understood from the following detailed description taken in conjunction with the accompanying drawings, in which:

FIG. 1 is a schematic block configuration diagram of a digital twin system to which an embodiment is applied;

FIG. 2 is a schematic block configuration diagram of a federated digital twin system according to an embodiment;

FIG. 3 is a schematic block configuration diagram of a digital twin federation apparatus associated with an application service layer according to an embodiment;

FIG. 4 is an operation flowchart between detailed components of a registration unit according to an embodiment;

FIGS. 5 to 7 illustrate examples of a metadata standard system according to an embodiment;

FIG. 8 is a block diagram illustrating the internal configuration of a validation unit according to an embodiment;

FIG. 9 is a block diagram illustrating the internal configuration of a federation synchronization unit according to an embodiment;

FIG. 10 is a flowchart for explaining a digital twin federation method according to an embodiment; and

FIG. 11 is a diagram illustrating the configuration of a computer system according to an embodiment.

### DESCRIPTION OF THE PREFERRED EMBODIMENTS

Advantages and features of the present disclosure and methods for achieving the same will be clarified with reference to embodiments described later in detail together with the accompanying drawings. However, the present disclosure is capable of being implemented in various forms, and is not limited to the embodiments described later, and these embodiments are provided so that this disclosure will be thorough and complete and will fully convey the scope of the present disclosure to those skilled in the art. The present disclosure should be defined by the scope of the accompanying claims. The same reference numerals are used to designate the same components throughout the specification.

It will be understood that, although the terms “first” and “second” may be used herein to describe various components, these components are not limited by these terms. These terms are only used to distinguish one component from another component. Therefore, it will be apparent that a first component, which will be described below, may alternatively be a second component without departing from the technical spirit of the present disclosure.

The terms used in the present specification are merely used to describe embodiments, and are not intended to limit the present disclosure. In the present specification, a singular expression includes the plural sense unless a description to the contrary is specifically made in context. It should be understood that the term “comprises” or “comprising” used in the specification implies that a described component or step is not intended to exclude the possibility that one or more other components or steps will be present or added.

Unless differently defined, all terms used in the present specification can be construed as having the same meanings as terms generally understood by those skilled in the art to which the present disclosure pertains. Further, terms defined in generally used dictionaries are not to be interpreted as having ideal or excessively formal meanings unless they are definitely defined in the present specification.

A digital twin is a technology convergence platform that replicates or reproduces the physical world (real world) in the digital world to solve complicated problems and create new industrial and service ecosystems. More specifically, the digital twin is a convergence technology that synchronizes physical entities and their digital entities simulating the physical entities across time and space, analyzes situations for various purposes, and optimizes the physical entities by making predictions based on simulation results. Therefore, when the digital twin is utilized, limitations in time, cost, space, and information to solve the problems of the real world may be overcome.

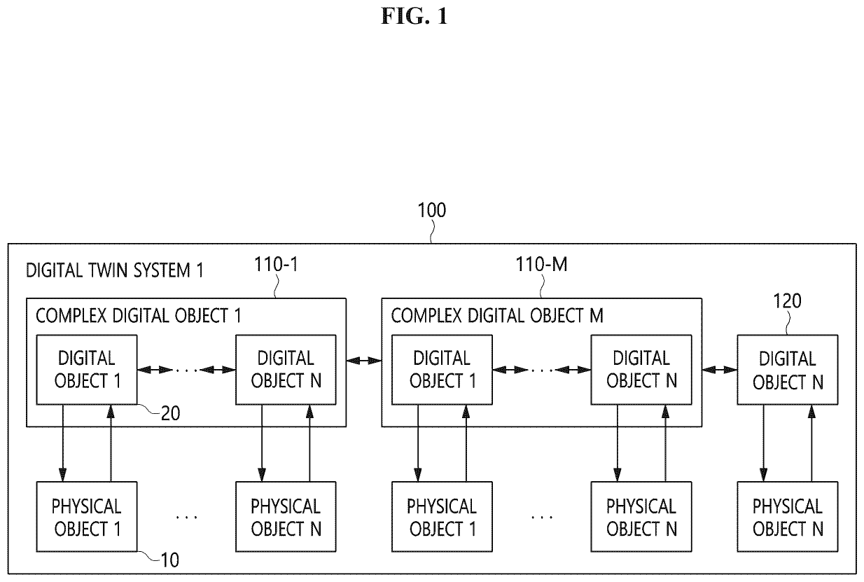

Until now, the digital twin has the form of a single digital twin. The single digital twin refers to a form in which a digital twin is constructed and operated by targeting a single system or a single process. Examples of such a single digital twin include a river digital twin that predicts river flooding and a manufacturing digital twin that forecasts productivity in a jet engine production plant. To construct the single digital twin, multiple objects or variables required by the target system need to be considered as inputs. In the river digital twin, rainfall, snowfall, flow velocity, water volume, and the like may be considered as input variables. In the manufacturing digital twin, multiple raw material parts, production equipment, manufacturing processes, and the like may be considered as input values. In the river digital twin, whether the river will flood may be considered as an output variable. In the manufacturing digital twin, the production time required for a single manufactured jet engine or the production volume over a specific period may be considered as an output variable. Such digital twin models may be illustrated in FIG. 1.

FIG. 1 is a schematic block configuration diagram of a digital twin system to which an embodiment is applied.

Referring to FIG. 1, a digital twin system 100 to which the embodiment is applied may include one or more complex digital objects 110-1, . . . , 110-M and a single digital object 120.

The single digital object 120 may be formed by simulating a physical object, and may be simulated based on data by utilizing various sensors, drivers, etc.

Each of the complex digital objects 110-1, . . . , 110-M may be composed of multiple digital objects.

An example of a complex digital object is a vehicle, which can be composed of combinations of various single physical objects such as an engine, wheels, and windows. Therefore, to simulate a vehicle as a digital object, a combination of various single digital objects is required.

However, when a complicated actual system needs to be constructed as a digital twin or when a service in which a complicated environment is taken into consideration needs to be provided based on a digital twin, if the digital twin is constructed using only the digital twin system 100, the number of physical objects, single digital objects, and complex digital objects to be managed by one digital twin system may greatly increase, and thus complexity in actual implementation increases.

In this case, federating multiple digital twin systems to construct a single large federated digital twin system may be an alternative. When the above-described multiple single digital twin systems are federated, such a method is intended to construct a federated digital twin by guaranteeing operation and management independency for respective single digital twins and federating the output data of the single digital twins.

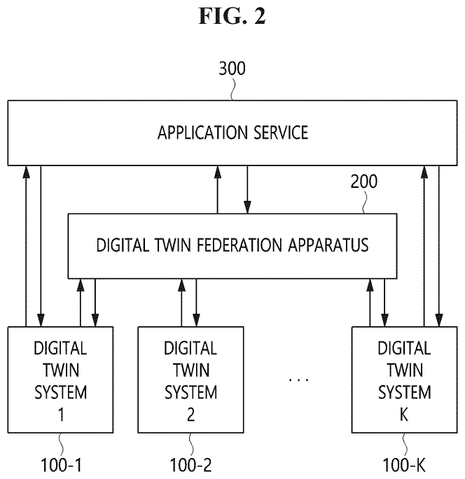

FIG. 2 is a schematic block configuration diagram of a federated digital twin system according to an embodiment.

Referring to FIG. 2, the federated digital twin system according to an embodiment has a configuration in which at least two digital twin systems 100-1, 100-2, . . . , 100-K are connected through a digital twin federation apparatus 200.

The digital twin federation apparatus 200 may configure a federated digital twin by linking at least two digital twin systems 100-1, 100-2, . . . , 100-K.

The federated digital twin system configured by the digital twin federation apparatus 200 may provide federated digital twin-based services to users through an application service layer 300.

Here, the application service may be a service for optimizing complicated systems, a service associated with digital twins in various fields, etc.

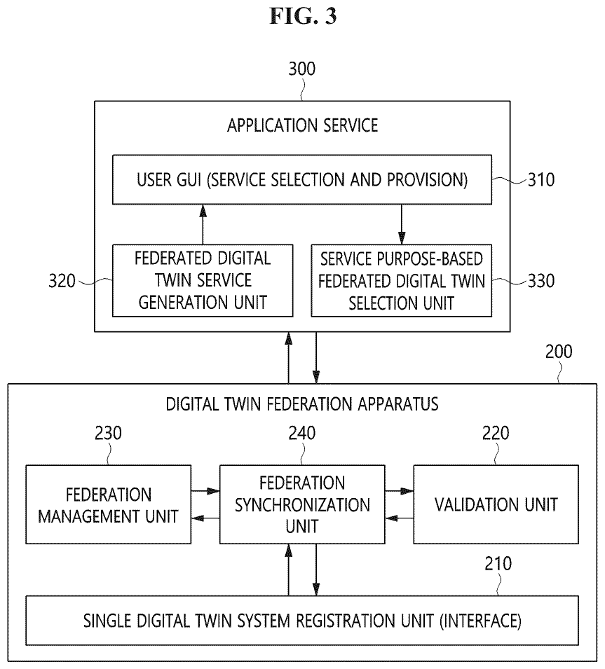

FIG. 3 is a schematic block configuration diagram of a digital twin federation apparatus associated with an application service layer according to an embodiment.

Referring to FIG. 3, single twin types for allowing a digital twin federation apparatus 200 according to an embodiment to configure a federated digital twin and output values of the digital twin federation apparatus 200 may be sorted and selected depending on the configuration purpose of the federated digital twin for application services.

The application service layer 300 functions to provide an application service depending on the requirements of the final user.

A user GUI 310 takes charge of direct communication between each user and the application service layer. That is, the service user selects a desired service through the user GUI 310 and requests the provision of the service. Such service provision requests are delivered to a service purpose-based federated digital twin selection unit 330.

The service purpose-based federated digital twin selection unit 330 selects a single digital twin system type and an output value required for providing a service and delivers the corresponding request to the digital twin federation apparatus.

Also, a federated digital twin service generation unit 320 functions to generate an application service by federating multiple pieces of single digital twin system data, which are received from the digital twin federation apparatus 100 and which are validated and synchronized.

The digital twin federation apparatus 200 according to the embodiment may include a single digital twin system registration unit (hereinafter also referred to as a registration unit) 210, a federation synchronization unit 230, and a federation management unit 240. In addition, the digital twin federation apparatus 200 may further include a validation (i.e., validity verification) unit 220.

The registration unit 210 may register at least one digital twin system, and may provide the data input/output interface of the registered at least one digital twin system.

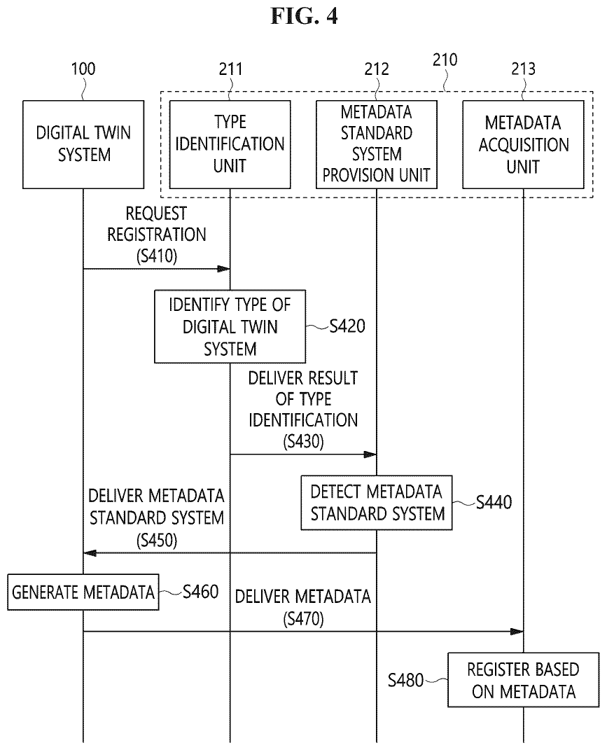

Here, the at least one digital twin system may be registered and managed based on metadata. Detailed description of the registration unit 210 will be made later with reference to FIGS. 4 to 7.

The validation unit 220 may determine whether errors occur in data obtained from the digital twin system and validate the operation of the corresponding digital twin system. That is, the validation unit 220 may receive multiple pieces of single digital twin data extracted by the federation management unit 240, determine whether errors/anomalies are present in the data, and validate the operation of the single digital twin system.

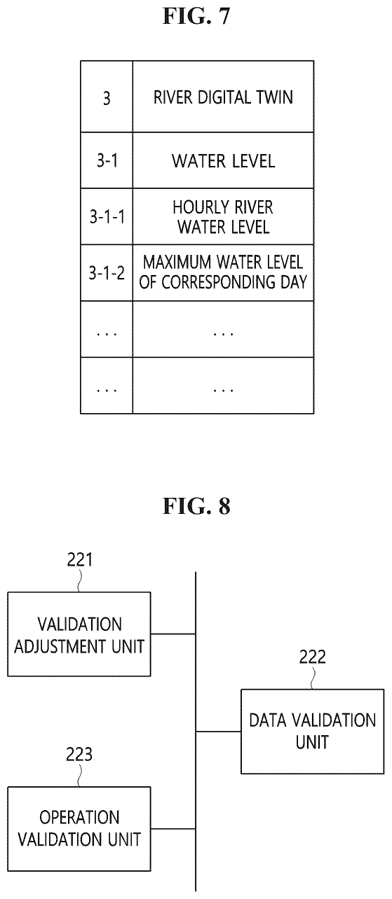

Here, the validation unit 220 may determine whether to operate depending on the importance of data. Detailed description of the registration unit 210 will be made later with reference to FIG. 8.

The federation synchronization unit 230 may synchronize pieces of data obtained from at least two digital twin systems so that the pieces of data are linked in the same time slot and the same unit.

That is, in order to provide the federated digital twin service, multiple pieces of single digital twin data extracted by the federation management unit are received, and synchronization between the pieces of data is performed.

The individual digital twin system operates and outputs data based on each operation and management policy. Therefore, data output times may be different from each other, or data output intervals may be different from each other. In this case, the federation synchronization unit 230 functions to align data output times, or correct and unify data output intervals for the purpose of smoothly linking and operating respective pieces of data. Detailed description of the federation synchronization unit 230 will be made later with reference to FIG. 8.

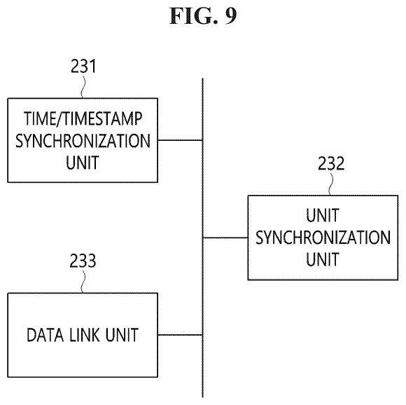

The federation management 240 links and manages single digital twins required in order to provide a federated digital twin service. Here, the federation management unit 240 functions to link and manage pieces of single digital twin data depending on a service purpose-based single digital twin list. Detailed description of the federation management unit 240 will be made later with reference to FIG. 9.

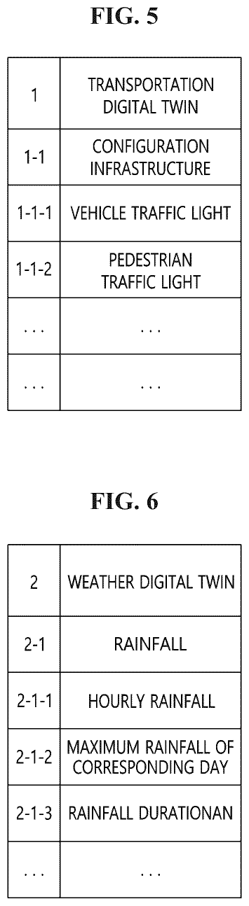

FIG. 4 is an operation flowchart between detailed components of a registration unit according to an embodiment, and FIGS. 5 to 7 illustrate examples of a metadata standard system according to an embodiment.

Referring to FIG. 4, the registration unit 210 according to the embodiment may include a type identification unit 211, a metadata standard system provision unit 212, and a metadata acquisition unit 213.

As the digital twin system 100 applies for new registration in the registration unit 210 at step S410, the type identification unit 211 identifies the type of the digital twin system 100 requested to be newly registered at step S420.

The type identification unit 211 identifies the type of the digital twin system 100 desired to be newly registered, determines whether to register the digital twin system 100 at step S420, and delivers the result of identification to the metadata standard system registration unit 212 at step S430.

Here, the type identification unit 211 may determine whether the identified type of the digital twin system 100 is included in the types of previously held digital twin systems.

Here, the types of the digital twin system may include, for example, transportation digital twin, a weather digital twin, a river digital twin, etc.

Here, when the identified type of the digital twin system 100 is a previously held type, the type of the new digital twin system may be delivered to the metadata standard system provision unit 212 at step S430.

On the other hand, when the identified type of the digital twin system 100 is not a previously held type, the type identification unit 211 notifies the metadata standard system provision unit 212 of the new type of digital twin at step S430.

The metadata standard system provision unit 212 detects a metadata system corresponding to the identified type of the digital twin system 100 at step S440, and delivers the metadata system to the corresponding digital twin system 100 at step S450.

FIGS. 5 to 7 illustrate examples of metadata standard systems provided for respective single digital twins.

Here, when the identified type of the digital twin system 100 is a previously held type, the metadata standard system provision unit 212 may deliver the previously held metadata system to the digital twin system 100 at step S450.

On the other hand, when the identified type of the digital twin system 100 is not a previously held type, the metadata system of the corresponding type is not held, and thus the metadata standard system provision unit 212 may deliver the metadata standard system of the digital twin system having a type, which is similar to that of the corresponding digital twin system, to the digital twin system 100 at step S450.

Then, the digital twin system 100 generates metadata by utilizing the metadata standard system received from the metadata standard system provision unit 212 at step S460, and thereafter delivers the generated metadata to the metadata acquisition unit 213 at step S470.

Here, when the received digital twin metadata standard system is identical to that of the digital twin system 100, the digital twin system 100 may generate metadata using the corresponding system, and may generate and add a new parameter as needed.

On the other hand, when the received digital twin metadata standard system is of a new type, the digital twin system 100 generates its own metadata by utilizing the received example metadata system.

The metadata acquisition unit 213 receives the metadata generated by the digital twin system 100 based on the metadata system, and stores the metadata as the registration information of the digital twin system 100 at step S480.

Through the above-described process, the digital twin system 100 may be registered and utilized in the digital twin federation apparatus 200.

FIG. 8 is a block diagram illustrating the internal configuration of a validation unit according to an embodiment.

Referring to FIG. 8, the validation unit 220 according to the embodiment may include a validation adjustment unit 221, a data validation unit 222, and an operation validation unit 223.

The validation unit 220 determines data validation accuracy of the requested digital twin system and time required for data validation.

Here, for data requiring near real-time processing, the data validation unit 220 simply determines whether errors or anomalies are present, and quickly delivers the validated data to the federation management unit 240.

On the other hand, when the data has high importance and requires a procedure such as accurate determination, error correction, or noise removal, the validation unit 220 forwards the corresponding situation to the data validation unit 222 or the operation validation unit 223 to enable a more precise validation process.

Therefore, when the data has high importance, the data validation unit 222 validates pieces of data of at least two digital twin systems using individual units, or may validate the pieces of data by linking the pieces of data based on correlation.

Furthermore, the operation validation unit 223 validates the operation of the single digital twin.

FIG. 9 is a block diagram illustrating the internal configuration of the federation synchronization unit according to an embodiment.

Referring to FIG. 9, the federation synchronization unit 230 according to the embodiment may include a time/timestamp synchronization unit 231, a unit synchronization unit 232, and a data link unit 233.

The time/timestamp synchronization unit 231 synchronizes times or output timestamps between pieces of data.

The unit synchronization unit 232 may unify the units of pieces of metadata when data units between pieces of metadata are different from each other (e.g., cm, inch, meter, feet, or the like).

The data link unit 233 may link pieces of data to each other so that pieces of data that are time synchronized and have a unified unit can be federated and used.

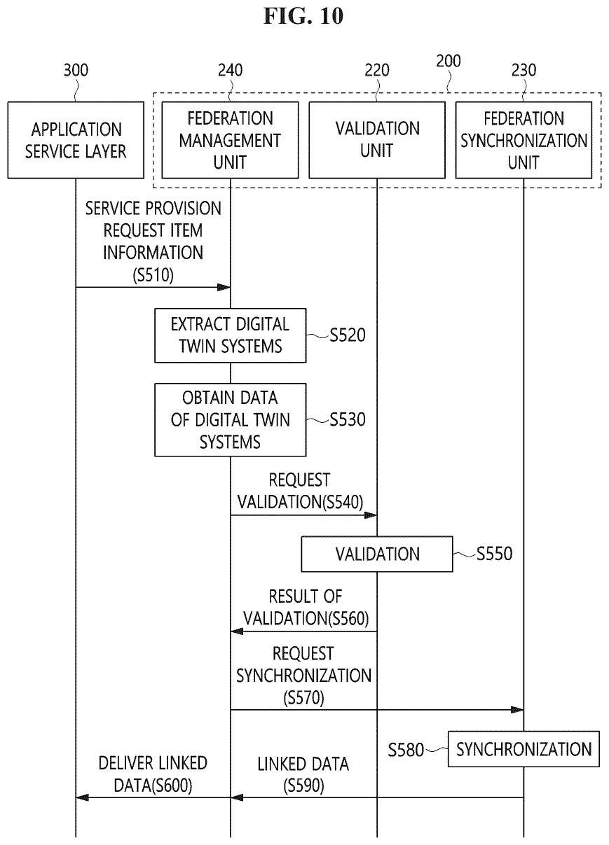

FIG. 10 is a flowchart for explaining a digital twin federation method according to an embodiment.

Referring to FIG. 10, in the digital twin federation method according to an embodiment, as service provision request item information is received from the application service layer 300 at step S510, the digital twin federation method may be initiated.

Next, the federation management unit 240 of the digital twin federation apparatus 200 extracts at least two digital twin systems corresponding to digital twin types matching a service purpose, received from the application service layer 300, from a pre-registered digital twin system list at step S520.

Thereafter, the federation management unit 240 obtains pieces of data from the extracted at least two digital twin systems, respectively, at step S530.

Here, the at least two digital twin systems may be those registered in the digital twin federation apparatus 200.

That is, the digital twin federation method according to an embodiment may further include the step of registering at least one digital twin system and the step of providing a data input/output interface of the registered at least one digital twin system.

Here, the registering step may include the step of identifying the type of digital twin system requested to be newly registered, the step of delivering a metadata system corresponding to the identified type of the digital twin system to the corresponding digital twin system, and the step of receiving metadata generated by the digital twin system based on the metadata system.

Here, the identifying step may include the step of determining whether the identified type of the digital twin system is included in the types of previously held digital twin systems.

Here, the delivering step may include the step of, when the identified type of the digital twin system is previously held type, delivering a previously held metadata system to the digital twin system.

Here, the delivering step may include the step of, when the identified type of the digital twin system is not previously held type, delivering the metadata standard system of a digital twin system having a type similar to that of the corresponding digital twin system to the digital twin system.

Thereafter, the federation management unit 240 delivers the obtained data to the validation unit 220 to perform steps S540 to S560 of determining whether errors are present in the obtained data and validating the operation of the corresponding digital twin system. However, whether to perform validating steps S540 to S560 may be selectively determined. That is, validating steps S540 to S560 may be skipped depending on the importance or the like of data.

Here, at validating step S550, the validation unit 220 may simply determine only whether errors are present and whether anomalies are present for data requiring near-real time processing.

Here, validating step S550 may be performed such that, when the importance of data is high, the validation unit 220 may validate pieces of data of at least two digital twin systems using individual units, or may validate the pieces of data by linking the pieces of data based on correlation.

Next, the federation management unit 240 may deliver the obtained data to the federation synchronization unit 230 to perform steps S570 to S590 of synchronizing pieces of data obtained from the extracted two or more digital twin systems so that the pieces of data are linked in the same time slot and in the same unit.

Here, at synchronization step S580, the federation synchronization unit 230 may check the metadata, unify the units of pieces of data when the units between pieces of data are different from each other, and synchronize times or timestamps with each other between the pieces of data to link the pieces of data so that the pieces of data are federated and used.

Finally, the federation management unit 240 delivers the linked data to the application service layer at step S600.

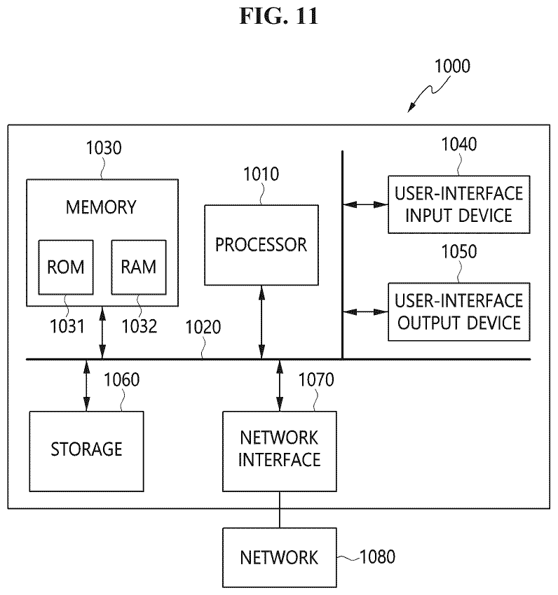

FIG. 11 is a diagram illustrating the configuration of a computer system according to an embodiment.

A digital twin federation apparatus 200 according to an embodiment may be implemented in a computer system 1000 such as a computer-readable storage medium.

The computer system 1000 may include one or more processors 1010, memory 1030, a user interface input device 1040, a user interface output device 1050, and storage 1060, which communicate with each other through a bus 1020. The computer system 1000 may further include a network interface 1070 connected to a network 1080. Each processor 1010 may be a Central Processing Unit (CPU) or a semiconductor device for executing programs or processing instructions stored in the memory 1030 or the storage 1060. Each of the memory 1030 and the storage 1060 may be a storage medium including at least one of a volatile medium, a nonvolatile medium, a removable medium, a non-removable medium, a communication medium or an information delivery medium, or a combination thereof. For example, the memory 1030 may include Read-Only Memory (ROM) 1031 or Random Access Memory (RAM) 1032.

According to embodiments, a digital twin may be easily constructed to target a large-scale physical world at the city or national level.

That is, the effect of implementing a large-scale digital twin may be obtained by linking previously constructed diverse digital twins without having to configure a large-scale significantly complicated digital twin. Therefore, the time and cost required in order to construct and operate a large-scale digital twin may be greatly reduced.

Although the embodiment of the present disclosure has been disclosed, those skilled in the art will appreciate that the present disclosure can be implemented as other concrete forms, without departing from the scope and spirit of the disclosure as disclosed in the accompanying claims. Therefore, it should be understood that the exemplary embodiment is only for illustrative purpose and do not limit the scope of the present disclosure.

What is claimed is:

1. A digital twin federation apparatus, comprising:
a memory configured to store at least one program; and
a processor configured to execute the program,
wherein the program performs:
extracting at least two digital twin systems corresponding to digital twin types matching a service purpose, received from an application service layer, from a pre-registered digital twin system list;
obtaining pieces of data from the extracted at least two digital twin systems, respectively;
synchronizing the pieces of data obtained from the extracted at least two digital twin systems, respectively, so that the pieces of data are linked in an identical time slot and in an identical unit; and
delivering the linked data to the application service layer.

2. The digital twin federation apparatus of claim 1, wherein the program further performs:
registering at least one digital twin system; and
providing a data input/output interface of the registered at least one digital twin system.

3. The digital twin federation apparatus of claim 2, wherein the program performs, in registering:
identifying a type of a digital twin system requested to be newly registered;
delivering a metadata system corresponding to the identified type of the digital twin system to the corresponding digital twin system; and
receiving metadata generated by the digital twin system based on the metadata system.

4. The digital twin federation apparatus of claim 3, wherein the program performs, in identifying:
determining whether the identified type of the digital twin system is included in types of previously held digital twin systems.

5. The digital twin federation apparatus of claim 4, wherein the program performs, in delivering:
when the identified type of the digital twin system is a type of a previously held digital twin system, delivering a previously held metadata system to the digital twin system.

6. The digital twin federation apparatus of claim 4, wherein the program performs, in delivering:
when the identified type of the digital twin system is not a type of a previously held digital twin system,
delivering a metadata standard system of a digital twin system having a type similar to that of the corresponding digital twin system to the digital twin system.

7. The digital twin federation apparatus of claim 1, wherein the program further performs:
determining whether an error occurs in the obtained data and validating an operation of the corresponding digital twin system.

8. The digital twin federation apparatus of claim 7, wherein the program performs, in validating:
simply determining only whether an error and an anomaly are present in data requiring near real-time processing.

9. The digital twin federation apparatus of claim 7, wherein the program performs, in validating:
when data has high importance, validating pieces of data of the two or more digital twin systems using individual units or validating the pieces of data by linking the data based on a correlation.

10. The digital twin federation apparatus of claim 1, wherein the program performs, in synchronizing:
checking metadata, unifying units of pieces of data when the units of the pieces of data are different from each other, and linking the pieces of data by synchronizing times or output timestamps between the pieces of data so that the pieces of data are federated and used.

11. A digital twin federation method, comprising:
extracting at least two digital twin systems corresponding to digital twin types matching a service purpose, received from an application service layer, from a pre-registered digital twin system list;
obtaining pieces of data from the extracted at least two digital twin systems, respectively;
synchronizing the pieces of data obtained from the extracted at least two digital twin systems, respectively, so that the pieces of data are linked in an identical time slot and in an identical unit; and
delivering the linked data to the application service layer.

12. The digital twin federation method of claim 11, further comprising:
registering at least one digital twin system; and
providing a data input/output interface of the registered at least one digital twin system.

13. The digital twin federation method of claim 12, wherein the registering comprises:
identifying a type of a digital twin system requested to be newly registered;
delivering a metadata system corresponding to the identified type of the digital twin system to the corresponding digital twin system; and
receiving metadata generated by the digital twin system based on the metadata system.

14. The digital twin federation method of claim 13, wherein the identifying comprises:
determining whether the identified type of the digital twin system is included in types of previously held digital twin systems.

15. The digital twin federation method of claim 14, wherein the delivering comprises;
when the identified type of the digital twin system is a type of a previously held digital twin system, delivering a previously held metadata system to the digital twin system.

16. The digital twin federation method of claim 14, wherein the delivering comprises:
when the identified type of the digital twin system is not a type of a previously held digital twin system,
delivering a metadata standard system of a digital twin system having a type similar to that of the corresponding digital twin system to the digital twin system.

17. The digital twin federation method of claim 11, further comprising:
determining whether an error occurs in the obtained data and validating an operation of the corresponding digital twin system.

18. The digital twin federation method of claim 17, wherein the validating comprises:
simply determining only whether an error and an anomaly are present in data requiring near real-time processing.

19. The digital twin federation method of claim 17, wherein the validating further comprises:
when data has high importance, validating pieces of data of the two or more digital twin systems using individual units or validating the pieces of data by linking the data based on a correlation.

20. The digital twin federation method of claim 11, wherein the synchronizing comprises:
checking metadata, unifying units of pieces of data when the units of the pieces of data are different from each other, and linking the pieces of data by synchronizing times or output timestamps between the pieces of data so that the pieces of data are federated and used.
